(19) United States
(12) Patent Application Publication
(10) Pub. No.: US 2026/0271415 A1
(43) Pub. Date: Sep. 10, 2026

(54) METHOD OF MANUFACTURING SOLID-STATE IMAGING DEVICE, AND SOLID-STATE IMAGING DEVICE

(71) Applicant: KANEKA CORPORATION, Osaka (JP)

(72) Inventors: Aoi Uozumi, Osaka (JP); Takuya Takahashi, Osaka (JP); Makoto Kutsumizu, Osaka (JP)

(73) Assignee: KANEKA CORPORATION, Osaka (JP)

(21) Appl. No.: 19/553,473

(22) Filed: Mar. 2, 2026

(30) Foreign Application Priority Data
Mar. 6, 2025 (JP) 2025-035284
Dec. 18, 2025 (JP) 2025-264063

(51) Int. Cl. H10F 39/00

(52) U.S. Cl. CPC H10F 39/804; H10F 39/011

(57) ABSTRACT

A method of manufacturing a solid-state imaging device, the device including a solid-state imaging element, a wiring substrate on which the solid-state imaging element is mounted, a transparent substrate facing the solid-state imaging element, and a frame disposed between the solid-state imaging element and the transparent substrate and that surrounds an imaging region of the solid-state imaging element, includes: bonding the solid-state imaging element to the wiring substrate via an adhesive and obtaining a mounted solid-state imaging element; forming the frame on the transparent substrate and obtaining a framed transparent substrate; and thermocompression-bonding the framed transparent substrate to the mounted solid-state imaging element. The thermocompression bonding includes placing the mounted solid-state imaging element on a stage.

### CROSS-REFERENCE TO RELATED APPLICATIONS

This application is based on and claims the benefit of priority from Japanese Patent Application No. 2025-035284, filed on 6 Mar. 2025, and Japanese Patent Application No. 2025-264063, filed on 18 Dec. 2025, the content of which is incorporated herein by reference.

### TECHNICAL FIELD

The present invention relates to a method of manufacturing a solid-state imaging device and to a solid-state imaging device.

### BACKGROUND

A solid-state imaging device that is an image sensor, such as a CMOS sensor or a CCD sensor, is known. Such a solid-state imaging device includes, for example, a solid-state imaging element (a semiconductor chip), a transparent substrate disposed so as to face the solid-state imaging element, and a frame disposed between the solid-state imaging element and the transparent substrate so as to surround an imaging region of the solid-state imaging element, and has a hollow structure in which the imaging region of the solid-state imaging element is sealed by the transparent substrate and the frame (see, for example, Patent Document 1).

### Patent Document

Patent Document 1: Japanese Unexamined Patent Application, Publication No. 2014-216475

In manufacturing such an imaging device, for example,
a solid-state imaging element is bonded to a wiring substrate via an adhesive to obtain a “solid-state imaging element mounted on a wiring substrate”,
a frame is formed on a transparent substrate to obtain a “transparent substrate with a frame”, and
the “transparent substrate with a frame” is thermocompression-bonded to the “solid-state imaging element mounted on a wiring substrate”.

In the thermocompression bonding step,
the “solid-state imaging element mounted on a wiring substrate” is placed on a stage,
the “transparent substrate with a frame” is sucked by a bond head via a collet and mounted on the “solid-state imaging element mounted on a wiring substrate”, and
while heating is performed by the stage or by the stage and the bond head, pressure is applied by the bond head via the collet to thermocompression-bond the “transparent substrate with a frame” to the “solid-state imaging element mounted on a wiring substrate”.

In manufacturing such an imaging device, when the solid-state imaging element is bonded to the wiring substrate, a thickness of the adhesive may become non-uniform, and the solid-state imaging element may tilt. When a frame is formed by patterning a resin composition, a frame having a high aspect ratio of height to width can be obtained, but such a frame is unlikely to undergo shape deformation.

Therefore, when the solid-state imaging element tilts, during thermocompression bonding of the “transparent substrate with a frame” to the “solid-state imaging element mounted on a wiring substrate”, a load applied to a portion of the frame located on a side where the height of the solid-state imaging element is higher becomes large, and there is a concern that reliability of the solid-state imaging device (reflow resistance, heat cycle resistance, and the like) may decrease.

### SUMMARY

One or more embodiments of the present invention provide a method of manufacturing a solid-state imaging device, and a solid-state imaging device, which suppress a decrease in reliability.

A method of manufacturing a solid-state imaging device according to the present invention is a method of manufacturing a solid-state imaging device including a solid-state imaging element, a wiring substrate on which the solid-state imaging element is mounted, a transparent substrate disposed so as to face the solid-state imaging element, and a frame disposed between the solid-state imaging element and the transparent substrate so as to surround an imaging region of the solid-state imaging element, the method including:
a step of bonding the solid-state imaging element to the wiring substrate via an adhesive to obtain a “solid-state imaging element mounted on a wiring substrate”;
a step of forming the frame on the transparent substrate to obtain a “transparent substrate with a frame”; and
a step of thermocompression-bonding the “transparent substrate with a frame” to the “solid-state imaging element mounted on a wiring substrate”.

In the step of thermocompression-bonding,
the “solid-state imaging element mounted on a wiring substrate” is placed on a stage,
the “transparent substrate with a frame” is sucked by a bond head via a collet and mounted on the “solid-state imaging element mounted on a wiring substrate”, and
while heating is performed by the stage or by the stage and the bond head, pressure is applied by the bond head via the collet to thermocompression-bond the “transparent substrate with a frame” to the “solid-state imaging element mounted on a wiring substrate”, thereby obtaining the solid-state imaging device. At least a portion of the collet includes a rubber-like material, and an elastic modulus of the at least the portion of the collet is 100 MPa or less.

A solid-state imaging device according to the present invention is a solid-state imaging device manufactured by the manufacturing method described above.

A solid-state imaging device according to the present invention includes: a solid-state imaging element; a wiring substrate on which the solid-state imaging element is mounted; a transparent substrate disposed so as to face the solid-state imaging element; and a frame disposed between the solid-state imaging element and the transparent substrate so as to surround an imaging region of the solid-state imaging element, in which the solid-state imaging element is bonded to the wiring substrate via an adhesive. When a difference between a height at one end of the solid-state imaging element and a height at the other end of the solid-state imaging element is defined as ΔT1, a difference between a height at one end of the wiring substrate and a height at the other end of the wiring substrate is defined as ΔT2, and a difference between a height at one end of the transparent substrate and a height at the other end of the transparent substrate is defined as ΔT3, an absolute value of (ΔT3−ΔT1) is smaller than an absolute value of (ΔT3−ΔT2).

Another solid-state imaging device according to the present invention includes: a solid-state imaging element; a wiring substrate on which the solid-state imaging element is mounted; a transparent substrate disposed so as to face the solid-state imaging element; and a frame disposed between the solid-state imaging element and the transparent substrate so as to surround an imaging region of the solid-state imaging element, in which the solid-state imaging element is bonded to the wiring substrate via an adhesive. When a difference between a height at one end of the solid-state imaging element and a height at the other end of the solid-state imaging element is defined as ΔT1, and a difference between a height on one side corresponding to one end of the solid-state imaging element and a height on the other side corresponding to the other end of the solid-state imaging element, among two opposing portions of the frame, is defined as ΔT4, a relationship of ΔT4<ΔT1 is satisfied.

According to the present invention, in a solid-state imaging device, a decrease in reliability caused by tilting of the solid-state imaging element resulting from non-uniform thickness of an adhesive can be suppressed.

### BRIEF DESCRIPTION OF THE DRAWINGS

FIG. 1 is a schematic diagram illustrating a solid-state imaging device according to one or more embodiments, as viewed from a light-receiving surface side;

FIG. 2 is a schematic cross-sectional view of the solid-state imaging device according to one or more embodiments, and is a cross-sectional view taken along the line II-II illustrated in FIG. 1;

FIG. 3A is a schematic diagram illustrating a step of obtaining a “transparent substrate with a frame” in a method of manufacturing the solid-state imaging device according to one or more embodiments;

FIG. 3B is a schematic diagram illustrating a step of obtaining a “transparent substrate with a frame” in the method of manufacturing the solid-state imaging device according to one or more embodiments;

FIG. 3C is a schematic diagram illustrating a step of obtaining a “transparent substrate with a frame” in the method of manufacturing the solid-state imaging device according to one or more embodiments;

FIG. 3D is a schematic diagram illustrating a step of obtaining a “transparent substrate with a frame” in the method of manufacturing the solid-state imaging device according to one or more embodiments;

FIG. 3E is a schematic diagram illustrating a step of obtaining a “transparent substrate with a frame” in the method of manufacturing the solid-state imaging device according to one or more embodiments;

FIG. 4A is a schematic diagram illustrating a step of obtaining a “solid-state imaging element mounted on a wiring substrate” in the method of manufacturing the solid-state imaging device according to one or more embodiments;

FIG. 4B is a schematic diagram illustrating a step of obtaining a “solid-state imaging element mounted on a wiring substrate” in the method of manufacturing the solid-state imaging device according to one or more embodiments;

FIG. 5A is a schematic diagram illustrating a combining step, particularly a thermocompression bonding step, of a “solid-state imaging element mounted on a wiring substrate” and a “transparent substrate with a frame” in the method of manufacturing the solid-state imaging device according to one or more embodiments;

FIG. 5B is a schematic diagram illustrating a combining step, particularly a thermocompression bonding step, of a “solid-state imaging element mounted on a wiring substrate” and a “transparent substrate with a frame” in the method of manufacturing the solid-state imaging device according to one or more embodiments;

FIG. 5C is a schematic diagram illustrating a combining step of a “solid-state imaging element mounted on a wiring substrate” and a “transparent substrate with a frame” in the method of manufacturing the solid-state imaging device according to one or more embodiments;

FIG. 5D is a schematic diagram illustrating a combining step of a “solid-state imaging element mounted on a wiring substrate” and a “transparent substrate with a frame” in the method of manufacturing the solid-state imaging device according to one or more embodiments;

FIG. 5E is a schematic diagram illustrating a combining step of a “solid-state imaging element mounted on a wiring substrate” and a “transparent substrate with a frame” in the method of manufacturing the solid-state imaging device according to one or more embodiments;

FIG. 6A is a schematic cross-sectional view of a collet used in the method of manufacturing the solid-state imaging device according to one or more embodiments, and is a cross-sectional view taken along the line VIA-VIA illustrated in FIG. 6B;

FIG. 6B is a schematic plan view of the collet used in the method of manufacturing the solid-state imaging device according to one or more embodiments;

FIG. 7A is a schematic cross-sectional view of a solid-state imaging device according to a modification example of one or more embodiments;

FIG. 7B is a schematic diagram illustrating a combining step, corresponding to the thermocompression bonding step illustrated in FIG. 5B, of a “solid-state imaging element mounted on a wiring substrate” and a “transparent substrate with a frame” in a method of manufacturing the solid-state imaging device according to the modification example of one or more embodiments; and

FIG. 8 is a schematic diagram illustrating a combining step, corresponding to the thermocompression bonding step illustrated in FIG. 5B, of a “solid-state imaging element mounted on a wiring substrate” and a “transparent substrate with a frame” in a method of manufacturing a solid-state imaging device according to a comparative example.

### DETAILED DESCRIPTION

Hereinafter, examples of one or more embodiments of the present invention will be described with reference to the accompanying drawings. In the drawings, the same or corresponding parts are denoted by the same reference numerals. For convenience, hatching, reference numerals of members, and the like may be omitted in some cases, and in such cases, other drawings are to be referred to.

### (Solid-State Imaging Device)

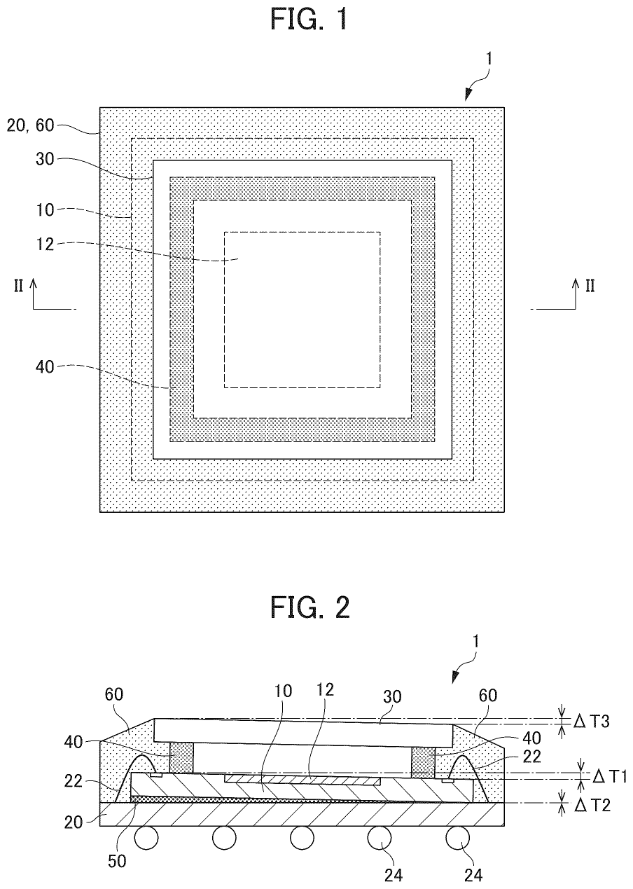

FIG. 1 is a schematic diagram illustrating a solid-state imaging device according to one or more embodiments, as viewed from a light-receiving surface side; and FIG. 2 is a schematic cross-sectional view of the solid-state imaging device according to one or more embodiments, and is a cross-sectional view taken along the line II-II illustrated in FIG. 1. A solid-state imaging device 1 illustrated in FIGS. 1 and 2 is an image sensor such as a CMOS sensor or a CCD sensor, and is a so-called GoC (Glass on Chip) type solid-state imaging device. The solid-state imaging device 1 includes a solid-state imaging element 10, a wiring substrate 20, a transparent substrate 30, and a frame (rib member) 40.

### <Solid-State Imaging Element>

The solid-state imaging element 10 is a semiconductor chip of an image sensor such as a CMOS sensor or a CCD sensor. The semiconductor chip is composed of, for example, a silicon substrate (wafer), and has an imaging region 12 including a plurality of pixels arranged two-dimensionally. Each pixel is composed of, for example, a photodiode. A color filter or a microlens may be disposed on the imaging region 12. The solid-state imaging element 10 is mounted on and bonded to the wiring substrate 20 via an adhesive 50.

As the adhesive 50, a photocurable adhesive, a thermosetting adhesive, or an adhesive having both photocurability and thermosetting properties can be used. Examples of the adhesive include curable resins such as an epoxy resin, an acrylic resin, and a silicone resin. The adhesive may include a filler such as silica from the viewpoint of viscosity adjustment or the like.

### <Wiring Substrate>

The wiring substrate 20 is a substrate on which wiring is formed. The wiring substrate 20 and the solid-state imaging element 10 are electrically connected by wiring 22 such as bonding wires. Conductive members 24 such as solder balls are electrically connected to the wiring substrate 20 in order to transmit signals and power between the solid-state imaging element 10 and an external component. The wiring 22 may be covered with a potting resin 60.

Examples of the wiring substrate 20 include organic materials such as polyimide, polyester, ceramic, epoxy, bismaleimide triazine, and phenolic resin, structures obtained by impregnating paper or glass-fiber nonwoven fabric with the organic materials described above and thermally curing the impregnated materials, ceramics such as alumina, aluminum nitride, beryllium oxide, and silicon nitride, and metal substrates. Among these materials, a glass epoxy substrate and a ceramic substrate may be used. A circuit having a metal wiring pattern, metal bumps, metal vias, or metal-film-coated through-holes can be formed on a surface of or inside such an insulating substrate. The wiring substrate 20 can have flexibility (flexible property or bendability).

As the potting resin 60, a photocurable resin composition, a thermosetting resin composition, or a resin composition having both photocurability and thermosetting properties can be used. Examples of the resin composition include curable resins such as an epoxy resin, an acrylic resin, and a silicone resin.

### <Transparent Substrate>

The transparent substrate 30 is disposed so as to face the solid-state imaging element 10, specifically, so as to face a main surface, of two main surfaces of the solid-state imaging element 10, on which the imaging region 12 is formed. As the transparent substrate 30, glass, an acrylic resin, or a transparent plastic such as polycarbonate can be used, and glass may be used from the viewpoint of reliability. The type of glass is not particularly limited, and examples include quartz glass, borosilicate glass, and alkali-free glass.

As necessary, a coating film such as an infrared reflective film (or an infrared cut filter), an antireflection film (AR coating), a protective film, or a reinforcing film can be formed on a surface of the transparent substrate 30. In particular, an antireflection film or an infrared reflective film (or an infrared cut filter) may be used because optical noise in a captured image is reduced. In particular, when the coating film is an antireflection film, the coating film may be a multilayer film including several compounds selected from TiO₂, Nb₂O₅, Ta₂O₅, CaF₂, SiO₂, Al₂O₃, MgS₂, ZrO₂, NiO, and MgF₂.

These coating films can be provided on both surfaces or on one surface of the glass. When the coating films are provided on both surfaces, the types of the coating films may be the same or different. It is also possible to laminate different coating films having the same function on one surface, and it is also possible to laminate different coating films having different functions. The number of laminated layers is not particularly limited, and a multilayer structure having several layers to several tens of layers can be employed.

### <Frame>

The frame (rib member) 40 is disposed between the solid-state imaging element 10 and the transparent substrate 30 so as to surround the imaging region 12 of the solid-state imaging element 10. The frame 40 is bonded to the solid-state imaging element 10 and the transparent substrate 30 by adhesive force of a material of the frame 40.

Examples of the frame 40 include a photocurable resin, a thermosetting resin, or a resin having both photocurability and thermosetting properties, such as an epoxy resin, an acrylic resin, or a silicone resin.

In this manner, in the solid-state imaging device 1, the imaging region 12 of the solid-state imaging element 10 is sealed by the transparent substrate 30 and the frame 40. The solid-state imaging device 1 has a hollow structure having a space above the imaging region 12 of the solid-state imaging element 10.

In the solid-state imaging device 1, due to non-uniform thickness of the adhesive 50, the solid-state imaging element 10 and the transparent substrate 30 are tilted with respect to the wiring substrate 20. For example, with respect to a height of the frame 40 of 40 μm (a width of 150 μm), a height of the adhesive 50 may become non-uniform by several tens of micrometers. As a result, a difference between a height of a surface at one end of the solid-state imaging element 10 and a height of a surface at the other end of the solid-state imaging element 10, and a difference between a height of a surface at one end of the transparent substrate 30 and a height of a surface at the other end of the transparent substrate 30, may be on the order of several tens of micrometers.

When a difference between a height of a surface at one end of the solid-state imaging element 10 and a height of a surface at the other end of the solid-state imaging element 10 is defined as ΔT1, a difference between a height of a surface at one end of the wiring substrate 20 and a height of a surface at the other end of the wiring substrate 20 is defined as ΔT2, and a difference between a height of a surface at one end of the transparent substrate 30 and a height of a surface at the other end of the transparent substrate 30 is defined as ΔT3, an absolute value of (ΔT3−ΔT1) is smaller than an absolute value of (ΔT3−ΔT2).

Here, the “height of a surface at one end of the solid-state imaging element 10” and the “height of a surface at the other end of the solid-state imaging element 10” refer to absolute heights from a horizontal plane when the solid-state imaging device 1 is placed on the horizontal plane. For example, when a rear surface of the wiring substrate 20 of the solid-state imaging device 1, excluding the conductive members 24, is placed on the horizontal plane, the heights correspond to absolute heights from the rear surface of the wiring substrate 20. Similarly, the “height of a surface at one end of the wiring substrate 20” and the “height of a surface at the other end of the wiring substrate 20” refer to absolute heights from the horizontal plane when the solid-state imaging device 1 is placed on the horizontal plane. For example, when the rear surface of the wiring substrate 20 of the solid-state imaging device 1, excluding the conductive members 24, is placed on the horizontal plane, the heights correspond to absolute heights from the rear surface of the wiring substrate 20. Similarly, the “height of a surface at one end of the transparent substrate 30” and the “height of a surface at the other end of the transparent substrate 30” refer to absolute heights from the horizontal plane when the solid-state imaging device 1 is placed on the horizontal plane. For example, when the rear surface of the wiring substrate 20 of the solid-state imaging device 1, excluding the conductive members 24, is placed on the horizontal plane, the heights correspond to absolute heights from the rear surface of the wiring substrate 20.

In other words, among two opposing portions of the frame 40, a portion on a side of one end of the solid-state imaging element 10 is defined as one portion (a left frame portion in FIG. 2), and a portion on a side of the other end of the solid-state imaging element 10 is defined as the other portion (a right frame portion in FIG. 2). When a difference between a height of the one frame portion and a height of the other frame portion is defined as ΔT4, a relationship of ΔT4<ΔT1 is satisfied. Here, the “height of the one frame portion” and the “height of the other frame portion” refer to heights of the respective frame portions themselves, and may be, for example, heights at a center in a longitudinal direction (a depth direction in FIG. 2) and a center in a width direction (a left-right direction in FIG. 2) of each frame portion.

### (Method of Manufacturing Solid-State Imaging Device)

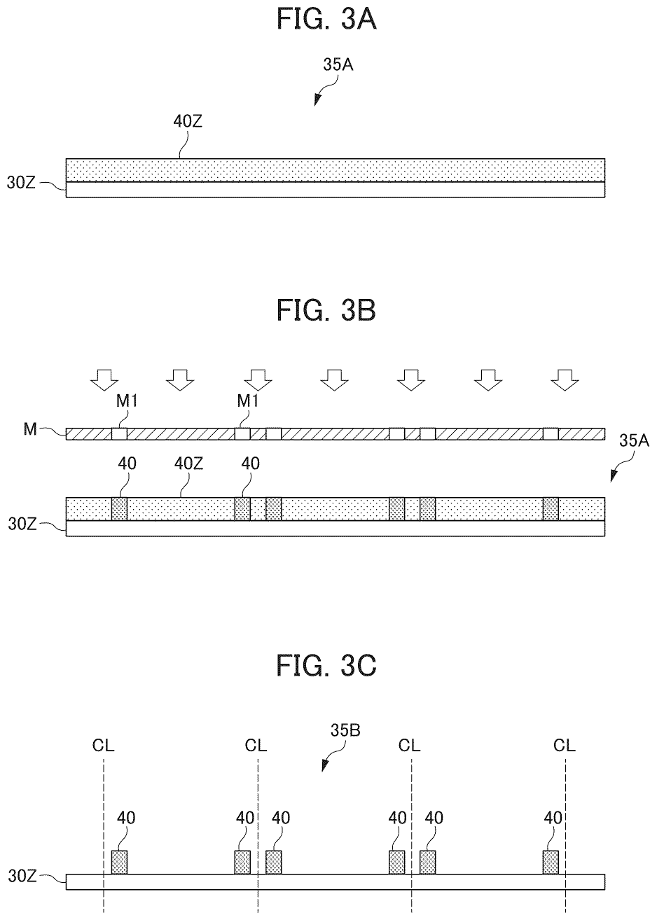

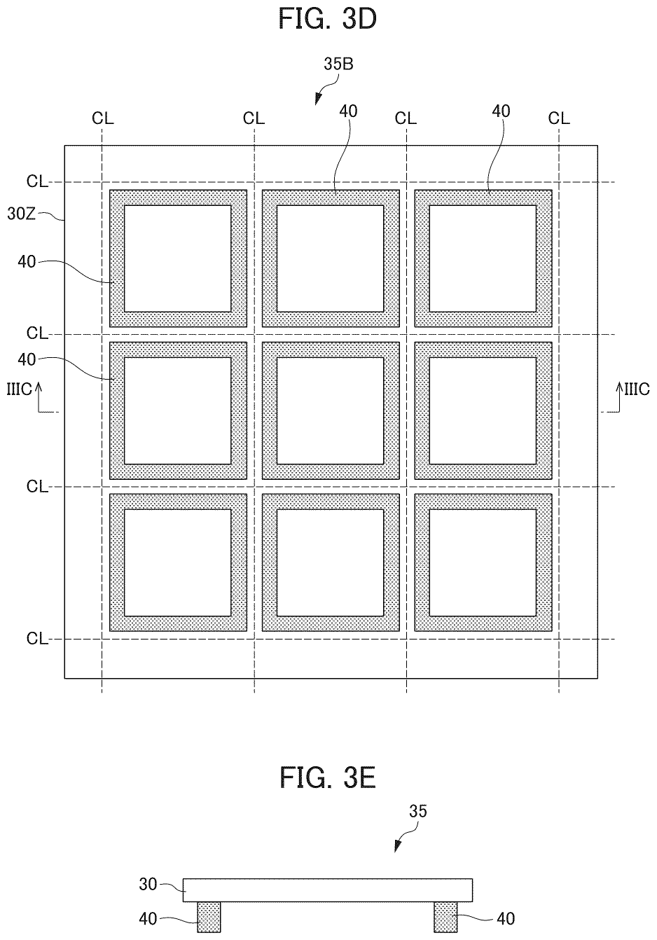

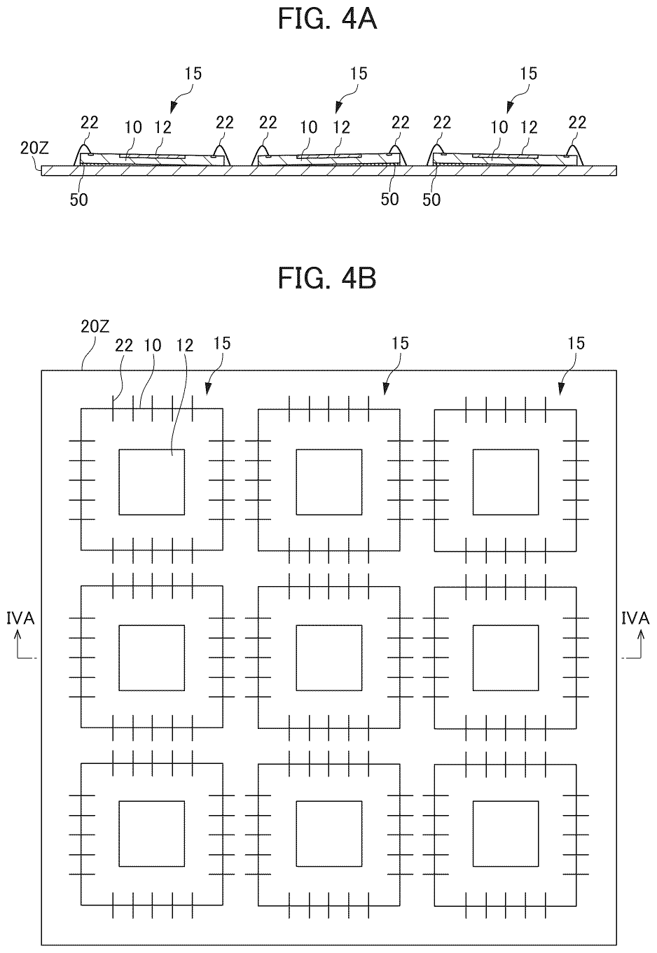

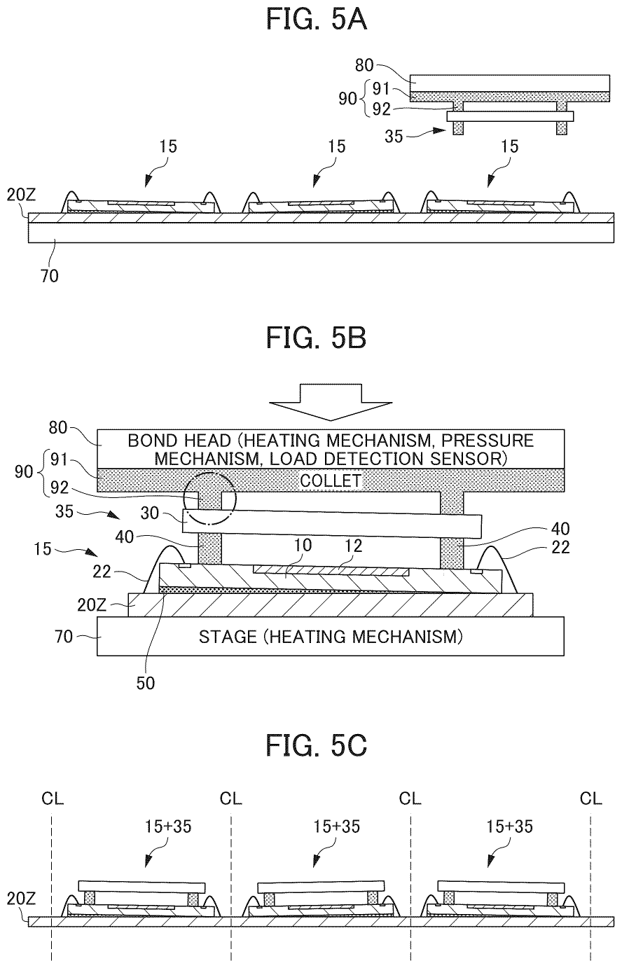

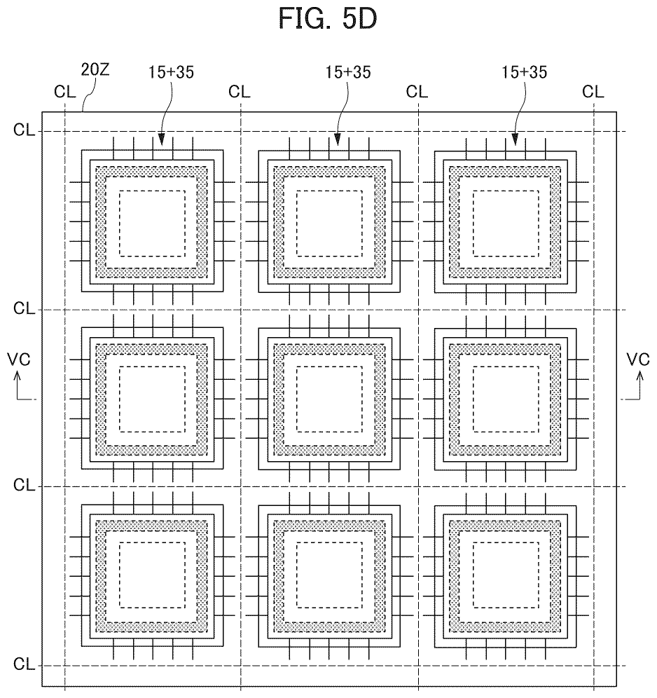

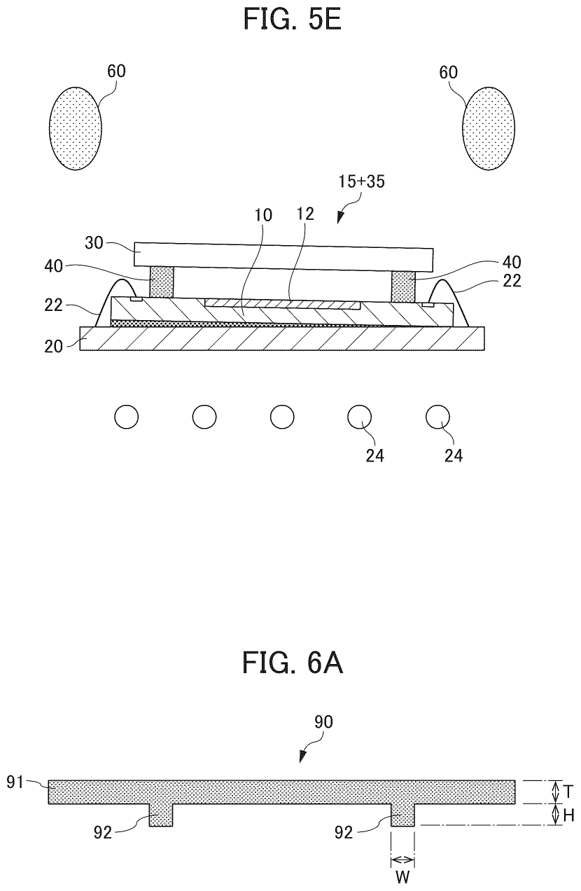

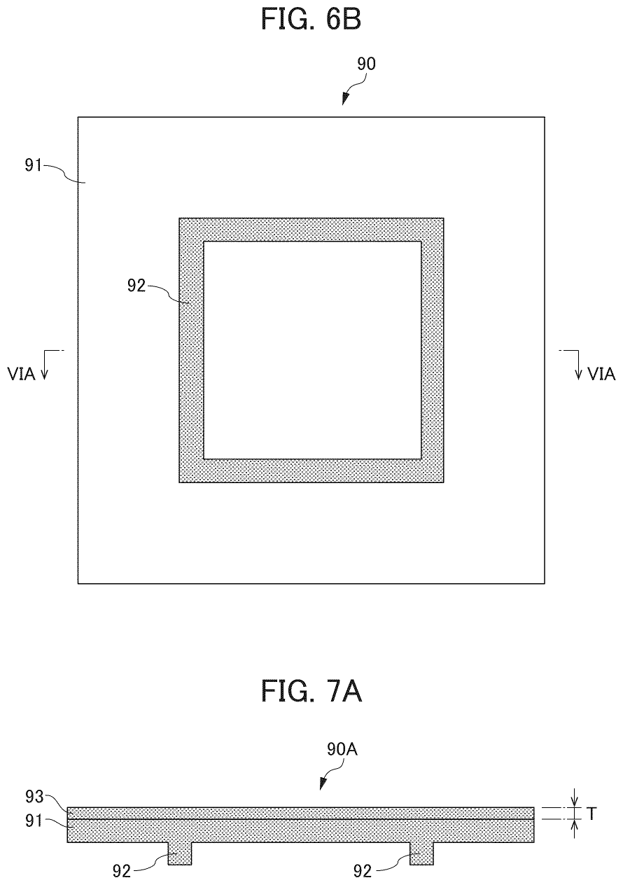

Next, a method of manufacturing the solid-state imaging device according to one or more embodiments will be described with reference to FIGS. 3A to 3E, FIGS. 4A to 4B, FIGS. 5A to 5E, and FIGS. 6A to 6B. FIGS. 3A to 3E are schematic diagrams illustrating steps of obtaining a “transparent substrate with a frame” in the method of manufacturing the solid-state imaging device according to one or more embodiments; and FIGS. 4A to 4B are schematic diagrams illustrating steps of obtaining a “solid-state imaging element mounted on a wiring substrate” in the method of manufacturing the solid-state imaging device according to one or more embodiments. FIGS. 5A to 5E are schematic diagrams illustrating a combining step of a “solid-state imaging element mounted on a wiring substrate” and a “transparent substrate with a frame” in the method of manufacturing the solid-state imaging device according to one or more embodiments, and FIGS. 5A to 5B particularly illustrate a thermocompression bonding step. FIG. 6A is a schematic cross-sectional view of a collet used in the method of manufacturing the solid-state imaging device according to one or more embodiments, and is a cross-sectional view taken along the line VIA-VIA illustrated in FIG. 6B; and FIG. 6B is a schematic plan view of the collet used in the method of manufacturing the solid-state imaging device according to one or more embodiments.

<Step of Obtaining “Transparent Substrate with a Frame”>

First, as illustrated in FIGS. 3A to 3E, a transparent substrate 30 on which the frame 40 is formed, that is, a “transparent substrate with a frame” 35, is manufactured. For example, as illustrated in FIG. 3A, a resin solution is applied to a large-sized transparent substrate 30Z to form a resin film 40Z (a first laminate 35A), and as illustrated in FIG. 3B, a portion 40 in the resin film 40Z is exposed using a photomask M (line pattern M1), and the exposed portion 40 is developed and patterned. Accordingly, as illustrated in FIGS. 3C and 3D, a plurality of frames (ribs, frame-shaped wall bodies obtained by patterning a resin composition) 40 are formed on the large-sized transparent substrate 30Z (a second laminate 35B). Thereafter, the large-sized transparent substrate 30Z is singulated along cut lines CL. Accordingly, as illustrated in FIG. 3E, a plurality of “transparent substrates with frames” 35 in each of which the frame 40 is formed on the transparent substrate 30 are obtained.

### <Step of Obtaining “Solid-State Imaging Element Mounted on a Wiring Substrate”>

As illustrated in FIGS. 4A and 4B, a solid-state imaging element 10 mounted on a wiring substrate 20, that is, a “solid-state imaging element mounted on a wiring substrate” 15, is manufactured. For example, a plurality of solid-state imaging elements 10 are bonded to a large-sized wiring substrate 20Z via an adhesive 50, and the plurality of solid-state imaging elements 10 are connected to the large-sized wiring substrate 20Z by wiring 22 such as bonding wires. Accordingly, a plurality of “solid-state imaging elements mounted on wiring substrates” 15 are obtained. Alternatively, a single “solid-state imaging element mounted on a wiring substrate” 15 may be obtained.

### <Combining Step>

### <<Thermocompression Bonding Step>>

Next, as illustrated in FIGS. 5A to 5D, a plurality of “transparent substrates with frames” 35 are respectively combined with a plurality of “solid-state imaging elements mounted on wiring substrates” 15. For example, as illustrated in FIG. 5A, a plurality of “solid-state imaging elements mounted on wiring substrates” 15 are placed on a stage 70. A bond head 80 sucks the “transparent substrates with frames” 35 one by one via a collet 90, and mounts each of the “transparent substrates with frames” 35 on a corresponding one of the plurality of “solid-state imaging elements mounted on wiring substrates” 15. The collet may be integrated with the bond head 80, or may be configured to be detachable.

Here, as illustrated in FIG. 5B, the stage 70 includes a heating mechanism that heats the “solid-state imaging elements mounted on wiring substrates” 15. The bond head 80 includes a heating mechanism that heats the “transparent substrates with frames” 35 via the collet 90. The bond head 80 includes a pressure mechanism that applies pressure to the “transparent substrates with frames” 35 via the collet 90. The bond head 80 includes a load detection sensor that detects a load applied by the pressure mechanism. These heating mechanisms and pressure mechanisms may be any known mechanisms, and the load detection sensor may be any known sensor.

The heating mechanism of the stage 70 and the heating mechanism of the bond head 80 may be automatically controlled by a control device (not illustrated) so as to reach predetermined temperatures, or may be manually controlled by an operator. The pressure mechanism of the bond head 80 may be automatically controlled by a control device (not illustrated) so as to reach a predetermined pressure based on a pressure detected by the load detection sensor of the bond head 80, or may be manually controlled by an operator.

In this manner, as illustrated in FIG. 5B, while heating is performed by the stage (heating mechanism) 70 or by the stage (heating mechanism) 70 and the bond head (heating mechanism) 80, pressure is applied by the bond head (pressure mechanism) 80 via the collet (load detection sensor) 90 to thermocompression-bond the “transparent substrate with a frame” 35 to the “solid-state imaging element mounted on a wiring substrate” 15.

### <Collet>

Here, as illustrated in FIGS. 6A and 6B, in one or more embodiments, the collet 90 includes a flat plate portion 91 and a rib portion 92. The rib portion 92 extends circumferentially along one main surface of the flat plate portion 91 and sucks the “transparent substrate with a frame” 35. In this manner, the collet 90 has a hollow structure on one main surface side, the hollow structure being surrounded by the flat plate portion 91 and the rib portion 92. A thickness T of the flat plate portion 91, a height H of the rib portion 92, and a width W of the rib portion 92 are as follows.
Thickness T of the flat plate portion 91: 0.5 mm or more and 10 mm or less, or 2 mm or more and 5 mm or less.
Height H of the rib portion 92: 0.1 mm or more and 0.5 mm or less, or 0.2 mm or more and 0.4 mm or less.
Width W of the rib portion 92: 0.15 mm or more and 0.8 mm or less, or 0.2 mm or more and 0.5 mm or less.

The collet 90 does not necessarily need to include the rib portion 92, and may be configured to include only the flat plate portion 91.

The rib portion 92 may be disposed at a position overlapping the frame 40 via the transparent substrate 30 of the “transparent substrate with a frame” 35.

The collet 90, that is, the entirety of the flat plate portion 91 and the rib portion 92, includes a rubber-like material, and an elastic modulus of the collet 90 is 100 MPa or less, or 80 MPa or less, or 30 MPa or less.

A Shore A hardness of the entirety of the collet 90, that is, the flat plate portion 91 and the rib portion 92, may be 80 or less, or 70 or less.

Examples of the rubber-like material include a silicone resin, a fluororesin, and a nitrile resin.

Next, as illustrated in FIGS. 5C and 5D, the large-sized wiring substrate 20Z is singulated along cut lines CL, and as illustrated in FIG. 5E, resin is potted onto wiring 22 such as bonding wires, the wiring 22 such as bonding wires is covered with the potting resin 60, and conductive members 24 such as solder balls are combined with and bonded to a rear surface side of the wiring substrate 20. Accordingly, the solid-state imaging device 1 illustrated in FIG. 2 is obtained.

The order of the combining step and the singulation step may be reversed. For example, after a plurality of “solid-state imaging elements mounted on wiring substrates” 15 are singulated, each of the “transparent substrates with frames” 35 may be combined with a corresponding one of the “solid-state imaging elements mounted on wiring substrates” 15 to obtain the solid-state imaging device 1 illustrated in FIG. 2.

Here, as illustrated in FIG. 4A, in a GoC-type solid-state imaging device 1, when the solid-state imaging element 10 is bonded to the large-sized wiring substrate 20Z, the thickness of the adhesive 50 may become non-uniform, and the solid-state imaging element 10 may tilt. For example, as illustrated in FIGS. 3A to 3D, when the frame 40 is formed by patterning a resin composition, a frame having a high aspect ratio of height to width can be obtained, but the frame 40 is unlikely to undergo shape deformation.

FIG. 8 is a schematic diagram illustrating a combining step of a “solid-state imaging element mounted on a wiring substrate” and a “transparent substrate with a frame” in a method of manufacturing a solid-state imaging device according to a comparative example, and illustrates a thermocompression bonding step corresponding to that illustrated in FIG. 5B. In the manufacturing method in this comparative example, as compared with the manufacturing method in the embodiments described above, a collet 90X composed of a material that is relatively unlikely to deform (such as a metal or a resin) is used instead of the collet 90 composed of a rubber-like material.

Therefore, as illustrated in FIG. 8, when the solid-state imaging element 10 tilts, during thermocompression bonding of the “transparent substrate with a frame” 35 to the “solid-state imaging element mounted on a wiring substrate” 15, a load applied to a portion of the frame 40 located on a side where the height of the solid-state imaging element 10 is higher (a portion surrounded by a one-dot chain line in FIG. 8) becomes large, and there is a concern that reliability of the solid-state imaging device 1 (reflow resistance, heat cycle resistance, and the like) may decrease.

In this regard, according to the method of manufacturing the solid-state imaging device of one or more embodiments, as illustrated in FIG. 5B, the collet 90, that is, the entirety of the flat plate portion 91 and the rib portion 92, includes a rubber-like material, and an elastic modulus of the entirety of the collet 90, that is, the flat plate portion 91 and the rib portion 92, is 100 MPa or less. Accordingly, during thermocompression bonding of the “transparent substrate with a frame” 35 to the “solid-state imaging element mounted on a wiring substrate” 15, followability of the “transparent substrate with a frame” 35 with respect to tilting of the solid-state imaging element 10 can be enhanced. That is, in accordance with tilting of the solid-state imaging element 10, the collet 90 deforms (a portion surrounded by a one-dot chain line in FIG. 5B), and the “transparent substrate with a frame” 35 can be tilted. Therefore, an increase in a load applied to a portion of the frame 40 located on a side where the height of the solid-state imaging element 10 is higher can be suppressed, and a decrease in reliability of the solid-state imaging device 1 (reflow resistance, heat cycle resistance, and the like) can be suppressed.

According to the method of manufacturing the solid-state imaging device of one or more embodiments, a Shore A hardness of the entirety of the collet 90, that is, the flat plate portion 91 and the rib portion 92, may be 80 or less. Accordingly, during thermocompression bonding of the “transparent substrate with a frame” 35 to the “solid-state imaging element 10 mounted on a wiring substrate 20” 15, followability of the “transparent substrate with a frame” 35 with respect to tilting of the solid-state imaging element 10 can be enhanced.

According to findings of the inventors of the present application, when the Shore A hardness of the collet 90 exceeds 80 (that is, when the material is hard), followability of the “transparent substrate with a frame” 35 with respect to tilting of the solid-state imaging element 10 is low. On the other hand, when the Shore A hardness of the collet 90 is less than 40 (that is, when the material is soft), heat resistance may be suffered.

According to the method of manufacturing the solid-state imaging device of one or more embodiments, the material of the entirety of the collet 90, that is, the flat plate portion 91 and the rib portion 92, may be composed of a silicone resin or a fluororesin. The silicone resin or the fluororesin has relatively high heat resistance. Accordingly, during thermocompression bonding of the “transparent substrate with a frame” 35 to the “solid-state imaging element mounted on a wiring substrate” 15, heating can be performed by the bond head 80.

According to the method of manufacturing the solid-state imaging device of one or more embodiments, a thickness of the collet 90 (for example, a thickness of the flat plate portion 91) may be 5 mm or less. Accordingly, during thermocompression bonding of the “transparent substrate with a frame” 35 to the “solid-state imaging element mounted on a wiring substrate” 15, heat transferability during heating by the bond head 80 is high.

According to findings of the inventors of the present application, when the thickness of the collet 90 (for example, the thickness of the flat plate portion 91) exceeds 5 mm, heat transferability of the collet 90 decreases during heating by the bond head 80, and bondability between the “solid-state imaging element mounted on a wiring substrate” 15 and the “transparent substrate with a frame” 35 decreases. On the other hand, when the thickness of the collet 90 (for example, the thickness of the flat plate portion 91) is less than 0.5 mm, followability of the “transparent substrate with a frame” 35 with respect to tilting of the solid-state imaging element 10 may be suffered.

According to the method of manufacturing the solid-state imaging device of one or more embodiments, the collet 90 has a hollow structure surrounded by the flat plate portion 91 and the rib portion 92. Accordingly, since a portion that sucks the “transparent substrate with a frame” 35 is only the rib portion 92, adhesion of foreign matter to the “transparent substrate with a frame” 35 can be reduced. Releasability of the collet 90 from the transparent substrate after thermocompression bonding can be enhanced, and thus overall bondability can be enhanced.

### Modification Example

In the embodiments described above, a mode has been described in which the collet 90, in which the entirety of the flat plate portion 91 and the rib portion 92 is composed of a rubber-like member, is used in the thermocompression bonding step illustrated in FIGS. 5A to 5B. In the present modification example, a mode will be described in which a collet in which only a portion is composed of a rubber-like member is used in the thermocompression bonding step.

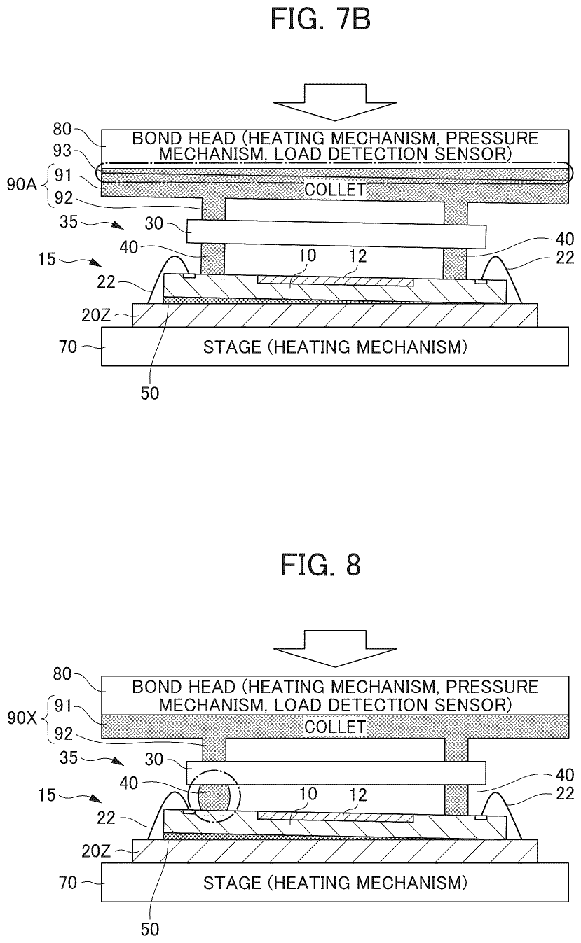

FIG. 7A is a schematic cross-sectional view of a collet used in a method of manufacturing a solid-state imaging device according to the modification example of one or more embodiments, and corresponds to the cross-sectional view illustrated in FIG. 6A. FIG. 7B is a schematic diagram illustrating a combining step of a “solid-state imaging element mounted on a wiring substrate” and a “transparent substrate with a frame” in the method of manufacturing the solid-state imaging device according to the modification example of one or more embodiments, and illustrates a thermocompression bonding step corresponding to that illustrated in FIG. 5B.

As illustrated in FIG. 7A, a collet 90A of the modification example includes a buffer layer 93 in addition to the flat plate portion 91 and the rib portion 92 described above. The buffer layer 93 is a plate-shaped buffer sheet disposed on the other main surface of the flat plate portion 91. A thickness T of the buffer layer 93 is 0.5 mm or more and 5.0 mm or less. The flat plate portion 91 and the rib portion 92 may be composed of the rubber-like member described above, or may be composed of a relatively deformation-resistant member such as a metal or a resin.

At least a portion of the buffer layer 93 of the collet 90 includes a rubber-like material, and an elastic modulus of the at least the portion of the buffer layer 93 of the collet 90 is 100 MPa or less, or 80 MPa or less, or 30 MPa or less.

A Shore A hardness of the at least the portion of the buffer layer 93 of the collet 90 may be 80 or less, or 70 or less.

Examples of the rubber-like material include a silicone resin, a fluororesin, and a nitrile resin.

Also in the manufacturing method in this modification example, advantages similar to those of the method of manufacturing the embodiments described above can be achieved. As illustrated in FIG. 7B, during thermocompression bonding of the “transparent substrate with a frame” 35 to the “solid-state imaging element mounted on a wiring substrate” 15, followability of the “transparent substrate with a frame” 35 with respect to tilting of the solid-state imaging element 10 can be enhanced. That is, in accordance with tilting of the solid-state imaging element 10, at least the buffer layer 93 of the collet 90 deforms (a portion surrounded by a one-dot chain line in FIG. 7B), and the “transparent substrate with a frame” 35 can be tilted. Therefore, an increase in a load applied to a portion of the frame 40 located on a side where the height of the solid-state imaging element 10 is higher can be suppressed, and a decrease in reliability of the solid-state imaging device 1 (reflow resistance, heat cycle resistance, and the like) can be suppressed.

Although embodiments of the present invention have been described above, the present invention is not limited to the embodiments described above, and various modifications and variations are possible. For example, in the embodiments described above, a so-called GoC (Glass on Chip) type solid-state imaging device (FIG. 2) has been exemplified. However, the features of the present invention are not limited thereto, and the present invention is applicable to various types of solid-state imaging devices.

### EXAMPLES

Hereinafter, the present invention will be specifically described based on examples, but the present invention is not limited to the following examples.

First, in each of Examples and Comparative Examples, a “transparent substrate with a frame” 35 and a “solid-state imaging element mounted on a wiring substrate” 15 were prepared.

(Transparent Substrate with a Frame)

### <Solution A Containing Resin A>

A dissolved material was obtained by dissolving 40 g of diallyl isocyanurate and 29 g of diallyl monomethyl isocyanurate in 264 g of dioxane. Next, 143 μL of a xylene solution of a platinum vinyl siloxane complex (a platinum vinyl siloxane complex containing 3 mass % of platinum, manufactured by Umicore Precious Metals Japan, Pt-VTSC-3X) was added to the dissolved material to obtain Solution 1.

A solution 2 was obtained by dissolving 88 g of 1,3,5,7-tetrahydrogen-1,3,5,7-tetramethylcyclotetrasiloxane in 176 g of toluene. Then, while the solution 2 was heated to 105° C. under a nitrogen atmosphere (containing 3% oxygen), the solution 1 was added dropwise to the solution 2 over 3 hours, and the state was maintained for 30 minutes after completion of the dropwise addition to obtain a solution 3. When a reaction rate of alkenyl groups of a compound contained in the solution 3 was measured by 1H-NMR, the reaction rate was 95% or more.

A solution 4 was obtained by dissolving 62 g of 1-vinyl-3,4-epoxycyclohexane in 62 g of toluene. Then, while the solution 3 was heated to 105° C. under a nitrogen atmosphere (containing 3% oxygen), the solution 4 was added dropwise to the solution 3 over 1 hour, and the state was maintained for 30 minutes after completion of the dropwise addition to obtain a solution 5. After confirming that a reaction rate of alkenyl groups of a compound contained in the solution 5 was 95% or more, the solution 5 was cooled to terminate the reaction.

Next, solvents (toluene and dioxane) were removed from the solution 5 under reduced pressure to obtain a solid content, and propylene glycol 1-monomethyl ether 2-acetate was added to the solid content to obtain a solution A containing 70 mass % of resin A.

### <Other Materials>

As materials for a curable composition, in addition to the solution A described above, the following materials were prepared.
Radical generator (2,2-dimethoxy-2-phenylacetophenone) (Omnirad 651, IGM Resins B.V.).
Trifunctional acrylic compound (tris-(2-acryloxyethyl) isocyanurate) (A-9300, Shin-Nakamura Chemical Co., Ltd.).
Colorant (carbon black MA100, manufactured by Mitsubishi Chemical Corporation).

### <Curable Composition>

A curable composition was prepared by mixing 100 g of the solution A, 0.07 g of Omnirad 651, 35 g of A-9300, and 0.175 g of carbon black MA100.

Next, as illustrated in FIG. 3A, the curable composition described above was applied by a spin coater onto a surface of a large-sized glass substrate 30Z having dimensions of 125 mm×125 mm×0.5 mm to form a coating film 40Z on the large-sized glass substrate 30Z, thereby obtaining a first laminate 35A. Next, the first laminate 35A was heated for 10 minutes on a hot plate heated to 125° C. to obtain the large-sized glass substrate 30Z on which a thin film 40Z having a thickness of 40 μm was formed.

Next, as illustrated in FIG. 3B, using an exposure apparatus (manual exposure apparatus, manufactured by Dainippon Scientific Co., Ltd.) (lamp: high-pressure mercury lamp), through a photomask M on which a line pattern M1 was formed in a lattice shape, a portion 40 of the coating film 40Z of the heated first laminate 35A was exposed by soft-contact exposure with an optimum integrated light amount. Next, the exposed first laminate 35A was heated for 10 minutes on a hot plate heated to 95° C. Accordingly, the exposed portion 40 of the coating film 40Z was brought into a semi-cured state.

Next, the first laminate 35A that had been left to stand for 1 minute was immersed for 60 seconds in an alkaline developer (alkaline component: TMAH; TMAH content: 2.38 mass %). Thereafter, the first laminate 35A immersed in the alkaline developer was washed with water for 30 seconds. Next, moisture on a surface of the washed first laminate 35A was removed with compressed air. Accordingly, as illustrated in FIGS. 3C and 3D, the thin film 40Z on the large-sized glass substrate 30Z was patterned, and the large-sized glass substrate 30Z provided with the frame 40 (rib member), which is a semi-cured frame-shaped (rectangular tubular) wall body, was obtained as a second laminate 35B.

Next, among surfaces of the second laminate 35B, a dicing film was temporarily bonded to a surface on which the frame 40 was not provided, and then the large-sized glass substrate 30Z was cut along cut lines CL between the frames 40 with a dicing blade into pieces having a size of 9 mm×6 mm. Thereafter, the dicing film was peeled off to obtain singulated “transparent substrates with frames” 35 illustrated in FIG. 3E (the frame 40 having a height of 40 μm and a width of 150 μm).

### (Solid-State Imaging Element Mounted on a Wiring Substrate)

As illustrated in FIGS. 4A and 4B, a plurality of solid-state imaging elements 10 were bonded to a large-sized wiring substrate 20Z via an adhesive 50, and the plurality of solid-state imaging elements 10 were connected to the large-sized wiring substrate 20Z by wiring 22 that are bonding wires, thereby obtaining a plurality of “solid-state imaging elements mounted on wiring substrates” 15. At this time, due to non-uniformity in thickness during application of the adhesive 50, each of the solid-state imaging elements 10 was tilted randomly.

### Example 1

Next, as illustrated in FIG. 5A, a plurality of “solid-state imaging elements mounted on wiring substrates” 15 were placed on the stage 70. Using a bonding machine (“CB-505” manufactured by Athlete FA Co., Ltd.), the “transparent substrates with frames” 35 were repeatedly laminated one by one onto respective ones of the “solid-state imaging elements mounted on wiring substrates” 15. Specifically, the collet 90 was installed on the upper bond head 80, and then each “transparent substrate with a frame” 35 was placed such that a surface on which the frame 40 was not provided was in contact with the collet 90.

Details of the collet 90 are as follows (FIGS. 6A to 6B, Tables 1 to 3).
A hollow structure including the flat plate portion 91 and the rib portion 92.
Thickness T of the flat plate portion 91: 0.5 mm.
Height H of the rib portion 92: 0.3 mm.
Width W of the rib portion 92: 0.5 mm.
Collet 90 (the entirety of the flat plate portion 91 and the rib portion 92): silicone resin (rubber-like material).
Elastic modulus of the collet 90 (the entirety of the flat plate portion 91 and the rib portion 92): 8.5 MPa.
Shore A hardness of the collet 90 (the entirety of the flat plate portion 91 and the rib portion 92): 70.

Thereafter, as illustrated in FIG. 5B, the bond head 80 and the stage 70 were heated to 100° C., and were brought close to the “solid-state imaging elements mounted on wiring substrates” 15. When a load detection sensor attached to the bond head 80 indicated 5 N, the state was maintained for 10 seconds, and suction of the “transparent substrates with frames” 35 by the collet 90 was released.

Next, as illustrated in FIGS. 5C and 5D, the large-sized wiring substrate 20Z was singulated along cut lines CL, and as illustrated in FIG. 5E, resin was potted onto wiring 22 such as bonding wires, the wiring 22 such as bonding wires was covered with the potting resin 60, and conductive members 24 such as solder balls were combined with and bonded to a rear surface side of the wiring substrate 20. Accordingly, as illustrated in FIGS. 1 and 2, the solid-state imaging device 1 of Example 1, in which the “transparent substrate with a frame” 35 was bonded to the “solid-state imaging element mounted on a wiring substrate” 15, was obtained.

### Examples 2 to 5

When bonding the “transparent substrate with a frame” 35 to the “solid-state imaging element mounted on a wiring substrate” 15, the procedures were performed in the same manner as in Example 1 except that a collet 90 (FIGS. 6A to 6B, Tables 1 to 3) different from the collet 90 of Example 1 in the following points was used.

### Example 2

Thickness T of the flat plate portion 91: 2 mm.

### Example 3

Thickness T of the flat plate portion 91: 3 mm.

### Example 4

Thickness T of the flat plate portion 91: 5 mm.

### Example 5

Thickness T of the flat plate portion 91: 10 mm.

### Examples 6 to 10

When bonding the “transparent substrate with a frame” 35 to the “solid-state imaging element mounted on a wiring substrate” 15, the procedures were performed in the same manner as in Example 2 except that a collet 90 (FIGS. 6A to 6B, Tables 1 to 3) different from the collet 90 of Example 2 in the following points was used.

### Example 6

Elastic modulus of the collet 90 (the entirety of the flat plate portion 91 and the rib portion 92): 30 MPa.

Shore A hardness of the collet 90 (the entirety of the flat plate portion 91 and the rib portion 92): 90.

### Example 7

Elastic modulus of the collet 90 (the entirety of the flat plate portion 91 and the rib portion 92): 80 MPa.

Shore A hardness of the collet 90 (the entirety of the flat plate portion 91 and the rib portion 92): greater than 90.

### Example 8

Elastic modulus of the collet 90 (the entirety of the flat plate portion 91 and the rib portion 92): 6.5 MPa.

Shore A hardness of the collet 90 (the entirety of the flat plate portion 91 and the rib portion 92): 70.

### Example 9

Elastic modulus of the collet 90 (the entirety of the flat plate portion 91 and the rib portion 92): 5.0 MPa.

Shore A hardness of the collet 90 (the entirety of the flat plate portion 91 and the rib portion 92): 60.

### Example 10

Elastic modulus of the collet 90 (the entirety of the flat plate portion 91 and the rib portion 92): 4.4 MPa.

Shore A hardness of the collet 90 (the entirety of the flat plate portion 91 and the rib portion 92): 50.

### Examples 11 to 12

When bonding the “transparent substrate with a frame” 35 to the “solid-state imaging element mounted on a wiring substrate” 15, the procedures were performed in the same manner as in Example 2 except that a collet 90 (FIGS. 6A to 6B, Tables 1 to 3) different from the collet 90 of Example 2 in the following points was used.

### Example 11

Collet 90 (the entirety of the flat plate portion 91 and the rib portion 92): fluororesin (rubber-like material).

Elastic modulus of the collet 90 (the entirety of the flat plate portion 91 and the rib portion 92): 7.8 MPa.

Shore A hardness of the collet 90 (the entirety of the flat plate portion 91 and the rib portion 92): 70.

### Example 12

Collet 90 (the entirety of the flat plate portion 91 and the rib portion 92): nitrile resin (rubber-like material).

Elastic modulus of the collet 90 (the entirety of the flat plate portion 91 and the rib portion 92): 10.2 MPa.

Shore A hardness of the collet 90 (the entirety of the flat plate portion 91 and the rib portion 92): 70.

### Example 13

When bonding the “transparent substrate with a frame” 35 to the “solid-state imaging element mounted on a wiring substrate” 15, the procedures were performed in the same manner as in Example 2 except that a collet 90A (FIG. 7A, Tables 1 to 3) different from the collet 90 of Example 2 in the following points was used.

Flat plate portion 91 and rib portion 92 (entirety): ceramic. Elastic modulus of the flat plate portion 91 and the rib portion 92 (entirety): 38 GPa.

Shore A hardness of the flat plate portion 91 and the rib portion 92 (entirety): greater than 90.

A hollow structure including the flat plate portion 91, the rib portion 92, and a buffer layer 93.

Thickness T of the buffer layer 93: 2 mm.

Buffer layer 93 (entirety): silicone resin (rubber-like material).

Elastic modulus of the buffer layer 93 (entirety): 8.5 MPa.

Shore A hardness of the buffer layer 93 (entirety): 70.

### Example 14

When bonding the “transparent substrate with a frame” 35 to the “solid-state imaging element mounted on a wiring substrate” 15, the procedures were performed in the same manner as in Example 2 except that a collet 90 (FIGS. 6A to 6B, Tables 1 to 3) different from the collet 90 of Example 2 in the following point was used.

A flat-plate structure including only the flat plate portion 91 and not including the rib portion 92.

### Comparative Example 1

When bonding the “transparent substrate with a frame” 35 to the “solid-state imaging element mounted on a wiring substrate” 15, the procedures were performed in the same manner as in Example 2 except that a collet 90X (FIG. 8, Tables 1 to 3) different from the collet 90 of Example 2 in the following points was used.

Collet 90X (the entirety of the flat plate portion 91 and the rib portion 92): ceramic.

Elastic modulus of the collet 90X (the entirety of the flat plate portion 91 and the rib portion 92): 38 GPa.

Shore A hardness of the collet 90X (the entirety of the flat plate portion 91 and the rib portion 92): greater than 90.

### Comparative Example 2

When bonding the “transparent substrate with a frame” 35 to the “solid-state imaging element mounted on a wiring substrate” 15, the procedures were performed in the same manner as in Example 2 except that a collet 90X (FIG. 8, Tables 1 to 3) different from the collet 90 of Example 2 in the following points was used.

Collet 90X (the entirety of the flat plate portion 91 and the rib portion 92): stainless steel.

Elastic modulus of the collet 90X (the entirety of the flat plate portion 91 and the rib portion 92): 205 GPa.

Shore A hardness of the collet 90X (the entirety of the flat plate portion 91 and the rib portion 92): greater than 90.

### (Evaluation)

Evaluation methods for respective evaluation items will be described.

### <Bonding Yield>

Bonding yield was calculated as follows. When 10 pieces were bonded, the number of pieces in which no peeling of the frame 40 was observed was confirmed by observation from a glass substrate 30 side of the solid-state imaging device using an optical microscope, and the bonding yield was calculated according to the following formula.

$$( Number of non - defective bonded pieces ) / ( total number of bonded pieces ) \times 100 = bonding yield ( \% ) .$$

### <Reliability>

Reliability evaluation was performed as follows. Using a heat shock test apparatus (“Cosmopia” (registered trademark) S manufactured by Hitachi Johnson Controls Air Conditioning, Inc.), the solid-state imaging device to be evaluated was held in an atmosphere of −50° C. for 30 minutes and then held in an atmosphere of 125° C. for 30 minutes, and this operation was defined as one cycle. A total of 500 cycles were performed. Next, the solid-state imaging device was observed from the glass substrate 30 side using an optical microscope, and the number of cracked portions of the frame 40 and the number of peeled portions of the frame 40 were counted. Then, reliability was determined according to the following criteria.

### <Reliability Determination Criteria>

A: Cracks or peeling occurred in two or more of three pieces.
B: Cracks or peeling occurred in one of three pieces.
C: Neither cracks nor peeling occurred in any of the three pieces.

### <Foreign Matter>

Observation was performed from the glass substrate 30 side of the solid-state imaging device using an optical microscope. Evaluation criteria are as follows.
∘: No foreign matter having a size of 100 μm or more adhered on the glass substrate 30, or foreign matter smaller than 100 μm adhered.
x: Foreign matter having a size of 100 μm or more adhered on the glass substrate.

Evaluation results of the respective evaluation items are as shown in Tables 1 to 3 below.

TABLE 1

| | | Difference in thickness | | | | |
|---|---|---|---|---|---|---|
| Collet | | Example 1 | Example 2 | Example 3 | Example 4 | Example 5 |
| Material | | Silicone | Silicone | Silicone | Silicone | Silicone |
| Thickness (mm) | | 0.5 | 2 | 3 | 5 | 10 |
| Shore A hardness | | 70 | 70 | 70 | 70 | 70 |
| Elastic modulus (Mpa) | | 8.5 | 8.5 | 8.5 | 8.5 | 8.5 |
| Shape | | Hollow | Hollow | Hollow | Hollow | Hollow |
| Insertion of buffer layer | | None | None | None | None | None |
| Material of buffer layer | | — | — | — | — | — |
| Thickness of buffer layer (mm) | | — | — | — | — | — |
| Elastic modulus of buffer layer | | — | — | — | — | — |
| (Mpa) | | | | | | |
| Evaluation | Bonding yield (%) | 50 | 90 | 90 | 70 | 50 |
| results | Reliability | A | A | A | A | B |
| | Foreign matter | ◯ | ◯ | ◯ | ◯ | ◯ |

TABLE 2

| | | Difference in Shore A hardness / difference in elastic modulus | | | | |
|---|---|---|---|---|---|---|
| Collet | | Example 6 | Example 7 | Example 8 | Example 9 | Example 10 |
| Material | | Silicone | Silicone | Silicone | Silicone | Silicone |
| Thickness (mm) | | 2 | 2 | 2 | 2 | 2 |
| Shore A hardness | | 90 | Greater | 70 | 60 | 50 |
| | | | than 90 | | | |
| Elastic modulus (Mpa) | | 30 | 80 | 6.5 | 5.0 | 4.4 |
| Shape | | Hollow | Hollow | Hollow | Hollow | Hollow |
| Insertion of buffer layer | | None | None | None | None | None |
| Material of buffer layer | | — | — | — | — | — |
| Thickness of buffer layer (mm) | | — | — | — | — | — |
| Elastic modulus of buffer layer | | — | — | — | — | — |
| (Mpa) | | | | | | |
| Evaluation | Bonding yield (%) | 90 | 70 | 95 | 95 | 90 |
| results | Reliability | A | A | A | A | A |
| | Foreign matter | ◯ | ◯ | ◯ | ◯ | ◯ |

TABLE 3

| | | | | Buffer material | | | |
|---|---|---|---|---|---|---|---|
| | | Difference in material | | (buffer layer) | | Comparative | Comparative |
| Collet | | Example 11 | Example 12 | Example 13 | Example 14 | Example 1 | Example 2 |
| Material | | Fluorine | Nitrile | Ceramic | Silicone | Ceramic | Stainless |
| | | | | | | | steel |
| Thickness (mm) | | 2 | 2 | 2 | 2 | 2 | 2 |
| Shore A hardness | | 70 | 70 | Greater | 70 | Greater | Greater |
| | | | | than 90 | | than 90 | than 90 |
| Elastic modulus (Mpa) | | 7.8 | 10.2 | 38000 | 8.5 | 38000 | 205000 |
| Shape | | Hollow | Hollow | Hollow | Plate- | Hollow | Hollow |
| | | | | | shaped | | |
| Insertion of buffer layer | | None | None | Present | None | None | None |
| Material of buffer layer | | — | — | Silicone | — | — | — |
| Thickness of buffer layer (mm) | | — | — | 2 | — | — | — |
| Elastic modulus of buffer layer | | — | — | 8.5 | — | — | — |
| (Mpa) | | | | | | | |
| Evaluation | Bonding yield (%) | 90 | 50 | 90 | 70 | 5 | 5 |
| results | Reliability | A | A | A | A | C | C |
| | Foreign matter | ◯ | ◯ | ◯ | X | ◯ | ◯ |

From results of Comparative Example 3 and Example 2, when the collet 90 did not have a hollow shape, the evaluation of foreign matter was rated as x. This is considered to be because the collet 90 contacted an entire surface of the glass substrate 30, and foreign matter adhering to the collet 90 was transferred.

From results of Examples 1 to 5, when a thickness of the collet 90 was 5 mm, bondability slightly decreased, and when the thickness was 10 mm, reliability also decreased. This is considered to be because heat conduction deteriorates as the thickness of the collet 90 increases.

From results of Comparative Examples 1 and 2, Example 2, and Examples 6 to 10, when the collet 90 had a high elastic modulus, bondability decreased. This is considered to be because, when the solid-state imaging element 10 is bonded to the wiring substrate 20, the thickness of the adhesive 50 may become non-uniform and the solid-state imaging element 10 may tilt, and the collet 90 could not follow such tilting.

From results of Example 2 and Examples 11 to 12, bondability decreased when a fluorine-based collet or a nitrile-based collet was used. This is considered to be because heat resistance of the fluorine-based or nitrile-based collet was low, and during bonding, the collet hardened, resulting in an increase in elastic modulus and a change in shape.

From results of Example 2 and Example 13, bondability was improved when the buffer layer 93 was inserted in the collet 90A. This is considered to be because insertion of the buffer layer 93 enables following of tilting of the solid-state imaging element 10 regardless of the elastic modulus of the rib portion 92 that is in contact with the transparent substrate.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### EXPLANATION OF REFERENCE NUMERALS

1: solid-state imaging device
10: solid-state imaging element
12: imaging region
15: solid-state imaging element mounted on wiring substrate
20: wiring substrate
20Z: large-sized wiring substrate
22: wiring
24: conductive member
30: transparent substrate
30Z: large-sized transparent substrate
35: transparent substrate with frame
35A: first laminate
35B: second laminate
40: frame (exposed portion)
40Z: thin film of resin composition
50: adhesive
60: resin
70: stage (heating mechanism)
80: bond head (heating mechanism, pressure mechanism, load detection sensor)
90, 90A, 90X: collet
91: flat plate portion
92: rib portion
93: buffer layer

1. A method of manufacturing a solid-state imaging device, the device including a solid-state imaging element, a wiring substrate on which the solid-state imaging element is mounted, a transparent substrate facing the solid-state imaging element, and a frame disposed between the solid-state imaging element and the transparent substrate and that surrounds an imaging region of the solid-state imaging element, the method comprising:
bonding the solid-state imaging element to the wiring substrate via an adhesive and obtaining a mounted solid-state imaging element;
forming the frame on the transparent substrate and obtaining a framed transparent substrate; and
thermocompression-bonding the framed transparent substrate to the mounted solid-state imaging element, wherein
the thermocompression-bonding comprises:
placing the mounted solid-state imaging element on a stage;
causing a bond head to suck the framed transparent substrate with a frame via a collet and to mount on the mounted solid-state imaging element; and
simultaneously causing either the stage of both the stage and the bond head to heat and causing the bond head to apply pressure via the collet,
a portion of the collet includes a rubber-like material, and
an elastic modulus of the portion of the collet is 100 MPa or less.

2. The method according to claim 1, wherein a Shore A hardness of the portion of the collet is 80 or less.

3. The method according to claim 1, wherein a material of the portion of the collet includes a silicone resin or a fluororesin.

4. The method according to claim 1, wherein a thickness of the portion of the collet is 5 mm or less.

5. The method according to claim 1, wherein
the collet includes:
a flat plate portion; and
a rib portion extending circumferentially along one main surface of the flat plate portion and configured to suck the framed transparent substrate,
the collet has a hollow structure surrounded by the flat plate portion and the rib portion, and
an entirety of the flat plate portion and the rib portion of the collet includes a rubber-like material.

6. The method according to claim 1, wherein
the collet includes:
a flat plate portion;
a rib portion extending circumferentially along a first main surface of the flat plate portion and configured to suck the framed transparent substrate; and
a plate-shaped buffer layer on a second main surface of the flat plate portion,
the collet has a hollow structure surrounded by the flat plate portion and the rib portion, and
the buffer layer of the collet includes a rubber-like material.

7. The method according to claim 5, wherein the rib portion of the collet is disposed at a position overlapping the frame.

8. The method according to claim 6, wherein the rib portion of the collet is disposed at a position overlapping the frame.

9. A solid-state imaging device manufactured by the method according to claim 1.

10. A solid-state imaging device, comprising:
a solid-state imaging element;
a wiring substrate on which the solid-state imaging element is mounted;
a transparent substrate facing the solid-state imaging element; and
a frame disposed between the solid-state imaging element and the transparent substrate and that surrounds an imaging region of the solid-state imaging element, wherein
the solid-state imaging element is bonded to the wiring substrate via an adhesive, and
an absolute value of (ΔT3−ΔT1) is smaller than an absolute value of (ΔT3-ΔT2) where
ΔT1 is a difference between a height at a first end of the solid-state imaging element and a height at a second end of the solid-state imaging element,
ΔT2 is a difference between a height at a first end of the wiring substrate and a height at a second end of the wiring substrate, and
ΔT3 is a difference between a height at a first of the transparent substrate and a height at a second end of the transparent substrate.

11. A solid-state imaging device, comprising:
a solid-state imaging element;
a wiring substrate on which the solid-state imaging element is mounted;
a transparent substrate facing the solid-state imaging element; and
a frame disposed between the solid-state imaging element and the transparent substrate and that surrounds an imaging region of the solid-state imaging element, wherein
the solid-state imaging element is bonded to the wiring substrate via an adhesive, and
ΔT4<ΔT1 where
ΔT1 is a difference between a height at a first end of the solid-state imaging element and a height at a second end of the solid-state imaging element, and
ΔT4 is a difference between a height of one portion of the solid-state imaging element on a side of a first end of the solid-state imaging element and a height of an opposing portion of the solid-state imaging element on a side of a second end of the solid-state imaging element.
